(19) United States
(12) Patent Application Publication
(10) Pub. No.: US 2023/0413444 A1
(43) Pub. Date: Dec. 21, 2023

(54) TUNING FORK FOR USE WITH A CIRCUIT BOARD

(71) Applicant: Sumitomo Wiring Systems, Ltd., Yokkaichi-shi (JP)

(72) Inventors: Cody Hicks, Farmington Hills, MI (US); Brian Carnick, Farmington Hills, MI (US)

(21) Appl. No.: 17/807,754

(22) Filed: Jun. 20, 2022

(51) Int. Cl. H05K 1/18

(52) U.S. Cl. CPC H05K 1/18; H05K 2201/10424

(57) ABSTRACT

A circuit board assembly includes a circuit board having a pair of slots spaced apart from each other and a terminal opening disposed between the pair of slots; and a tuning fork. The tuning fork includes a pair of terminals; a pair of shoulders, the pair of terminals attached to the pair of shoulders, each of the pair of shoulders extending orthogonal from a bottom of the pair of terminals; and a pair of supports extending upwardly from a corresponding one of the pair of shoulders, the pair of terminals disposed between the pair of support portions, the pair of support portions configured to engage a corresponding one of the pair of slots so as to place the pair of terminals within the terminal opening of the circuit board.

### TECHNICAL FIELD

The present specification generally relates to a tuning fork for use with a circuit board.

### BACKGROUND

Tuning forks are mounted to a top surface of a circuit board and are configured to engage an electronic component. A depiction of a conventional tuning fork 500 is shown in FIG. 1. The conventional tuning fork 500 includes a pair of terminals 502, a pair of shoulders 504 and a protrusion 506. The protrusion 506 is mounted to the top of a circuit board 508 and is inserted into a slit 510 of the circuit board 508. When mounted the height of electronic component (not shown) is increased by at least the height of the shoulders 504. Thus, the dimensions of a housing (not shown) which holds the circuit board 508 and the electronic component is constrained by the height of the electronic component resting on top of the circuit board 508.

Accordingly, it remains desirable to reduce the height of the housing by reducing the height of the electronic component when mounted onto the circuit board.

### SUMMARY

A tuning fork for attachment to a circuit board is provided. The tuning fork includes a pair of terminals and a pair of shoulders. Each of the pair of shoulders extend orthogonal from a bottom of the pair of terminals. The tuning fork further includes a pair of support portions extending upwardly from a corresponding one of the pair of shoulders. The pair of terminals is disposed between the pair of support portions. The pair of support portions is configured to engage a bottom surface of the circuit board. Accordingly, the height of an electronic component is reduced relative to conventional tuning forks.

In some configurations, the tuning fork further includes a base portion and the pair of terminals extending from the base portion.

In some configurations, each of the pair of terminals, the pair of shoulders, the pair of support portions and the base portion is a plate-shaped member.

In some configurations, the pair of terminals, the pair of shoulders, the pair of support portions and the base portion are coplanar.

In some configurations, each of the pair of shoulders includes an upright member and a transverse member, the transverse member being orthogonal to the upright member. In one aspect, each upright member is spaced apart from a corresponding one of the pair of terminals. In yet another aspect, each of the pair of support portions includes an end portion. The end portion may be tapered along at least one of a width, a height or a thickness of the corresponding one of the pair of support portions. In yet another aspect, the base portion includes a tool engagement feature.

In some configurations, each of the pair of terminals includes a bulbous member disposed on an inner surface of each of the pair of terminals so as to oppose each other.

A circuit board assembly is also provided. The circuit board assembly includes a circuit board and a tuning fork configured to engage an electric component. The circuit board includes a pair of slots spaced apart from each other and a terminal opening disposed between the pair of slots.

The tuning fork includes a pair of terminals, a pair of shoulders, and a pair of support portions. The pair of terminals is attached to the pair of shoulders so as to be interposed between the pair of shoulders. Each of the pair of shoulders extend orthogonal from a bottom of the pair of terminals. The pair of support portions extend upwardly from a corresponding one of the pair of shoulders. The pair of support portions is configured to engage the pair of slots so as to place the pair of terminals within the terminal opening of the circuit board.

In one configuration of the circuit board assembly, the circuit board includes a top surface and a bottom surface opposite of the top surface. In such a configuration, the circuit board assembly further includes an electronic component. In such a configuration, the pair of terminals are mounted to the bottom surface of the circuit board and the electronic component is mounted to the top surface of the circuit board so as to be disposed in the terminal opening and the pair of terminals are secured to the electronic component through the terminal opening. The electronic component may include a pair of second terminals, each of the pair of terminals of the tuning fork configured to engage a corresponding second terminal in the pair of second terminals in a pinch-fit manner.

In one configuration, the tuning fork further includes a base portion. The pair of terminals extend from the base portion. In one aspect, each of the pair of terminals, the pair of shoulders, the pair of support portions and the base portion is a plate-shaped member. In yet another aspect, the pair of terminals, the pair of shoulders, the pair of support portions and the base portion are coplanar.

In one configuration, each of the pair of shoulders includes an upright member and a transverse member. The transverse member is orthogonal to the upright member. In such a configuration, each upright member is spaced apart from a corresponding one of the pair of terminals.

In one configuration, each of the pair of support portions includes an end portion, the end portion being tapered along at least one of a width, a height or a thickness of the corresponding one of the pair of support portions.

In one configuration, the base portion includes a tool engagement feature and each of the pair of terminals includes a bulbous member disposed on an inner surface of each of the pair of terminals so as to oppose each other.

### Advantageous Effects

Accordingly, the tuning fork is configured to attach to the bottom surface of a circuit board wherein the electronic component may be seated lower relative to conventional tuning forks so as to lower the height of the electronic component relative to conventional tuning forks.

### BRIEF DESCRIPTION OF THE DRAWINGS

The embodiments set forth in the drawings are illustrative and exemplary in nature and not intended to limit the subject matter defined by the claims. The following description of the illustrative embodiments can be understood when read in conjunction with the following drawings, where like structure is indicated with like reference numerals and in which:

FIG. 1 is a perspective view of a conventional tuning fork mounted onto a circuit board;

FIG. 2 is a perspective view of a tuning fork according to one or more aspects described herein;

FIG. 3A is a top perspective view of an electronic component mounted to a circuit board assembly according to one or more aspects described herein;

FIG. 3B. is a close-up view of the electronic component shown in FIG. 3A;

FIG. 4A is a bottom perspective of the circuit board assembly shown in FIG. 3A;

FIG. 4B is a close-up view of the tuning fork shown in FIG. 4A; and

FIG. 5 is a cross-sectional view showing the tuning fork in FIG. 2 mounted to a bottom of a circuit board.

### DETAILED DESCRIPTION OF PREFERRED EMBODIMENTS

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed. Directional terms such as top, bottom, left and right are made in reference to the upright orientation of the drawings, and is indicated by directional arrows. The terms height, width, thickness and length are used in reference with the accompanying arrow.

Provided is a tuning fork and a circuit board assembly utilizing the tuning fork. The tuning fork includes a pair of terminals and a pair of shoulders. Each of the pair of shoulders extend orthogonal from a bottom of the pair of terminals. The tuning fork further includes a pair of support portions extending upwardly from a corresponding one of the pair of shoulders. The pair of terminals is disposed between the pair of support portions. The pair of support portions is configured to engage a bottom surface of the circuit board. Accordingly, the height of an electronic component is reduced relative to conventional tuning forks.

### The Tuning Fork

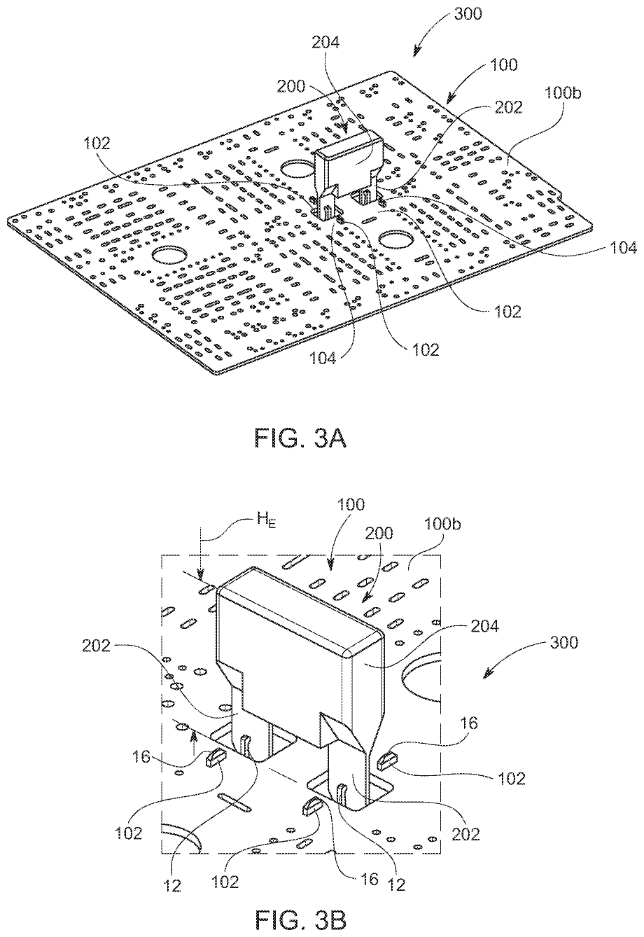

With reference now to FIG. 2 a description of an aspect of the tuning fork 10 is provided. The tuning fork 10 includes a pair of terminals 12 and a pair of shoulders 14 integrally formed with the pair of terminals 12. The pair of terminals 12 are disposed between the pair of shoulders 14. Each of the pair of shoulders 14 extends orthogonal from a bottom of the pair of terminals 12. The tuning fork 10 further includes a pair of support portions 16 extending upwardly from a corresponding one of the pair of shoulders 14. The pair of terminals 12 is disposed between the pair of support portions 16. The pair of support portions 16 is configured to engage a circuit board 100 (shown in FIGS. 3A-5).

The tuning fork 10 further may further include a base portion 18 formed on a bottom portion of the pair of terminals 12, wherein the pair of terminals 12 extending upwardly from the base portion 18. The base portion 18 may be centered with respect to a width “W_{T}” of the tuning fork 10. The base portion 18 may further include a tool engagement feature 20. In one aspect, the tool engagement feature 20 is an elongated opening extending through the base portion 18.

As show in FIG. 2, each of the pair of shoulders 14 includes an upright member 22 and a transverse member 24. The transverse member 24 is orthogonal to the upright member 22. Each upright member 22 is spaced apart from a corresponding one of the pair of terminals 12. The upright member 22 is offset from the end of the base portion 18 along a height “H_{T}” of the tuning fork 10. The shoulders 14 are positioned on the tuning fork 10 so as to make one half of the tuning fork 10 symmetrical to the other half when taken along an axis bifurcating the tuning fork 10 along the height “H_{T}” of the tuning fork 10.

Each of the pair of support portions 16 includes an end portion 26. The end portion 26 is spaced apart from the transverse member 24 by a height “H_{S}” of the support portion 16. The end portion 26 is shaped to facilitate an insertion into the circuit board 100. In one aspect, the end portion 26 is tapered along at least one of a width “W_{T}”, a height “H_{T}” or a thickness “T_{T}” of the tuning fork 10 and may include a planar top surface 100B 28 so as to form a truncated pyramid. The height “H_{S}” of each of the support portions 16 are preferably the same and is dimensioned to extend above the ends of the terminal 12.

In some configurations, each of the pair of terminals 12 includes a bulbous member 30 disposed on an inner surface 32 of each of the pair of terminals 12 so as to oppose each other. The terminals 12 are generally elongated plate-shaped members which may have a slight curve along its height “H_{T}” so as to be bowed. The bulbous members 30 are spaced apart from each other a distance smaller than a thickness “T_{E}” of a second terminal 202 of an electronic component 200, so as to generate a pinch fit engagement.

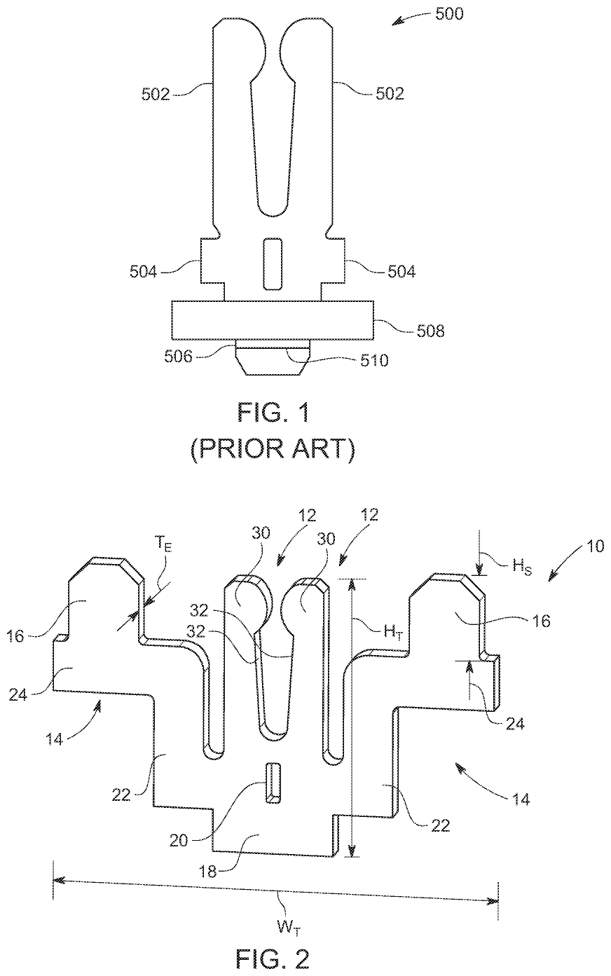

Preferably, the tuning fork 10 is formed as a unitary piece from an electrically conductive material. The tuning fork 10 may be manufactured by a stamping process. As such, the pair of terminals 12, the pair of shoulders 14, the pair of support portions 16 and the base portion 18 is a plate-shaped member. FIG. 1 depicts an aspect where the pair of terminals 12, the pair of shoulders 14, the pair of support portions 16 and the base portion 18 are coplanar. However, it should be appreciated that the pair of support portions 16 may be turned relative to the orientation shown in the drawings.

### The Circuit Board

The circuit board 100 is shown in FIGS. 3A-5. The circuit board 100 is a substrate formed of conductive and insulating layers. The substrate includes a bottom surface 100a opposite of a top surface 100b. Preferably, an electric conductive trace (not shown) is printed onto a top surface 100b of the circuit board 100 so as to complete an electric connection. The circuit board 100 includes a plurality of slits 102 extending through the circuit board 100. The slits 102 are generally elongated. In particular, the circuit board 100 includes two pairs of slits 102 and a terminal opening 104 is disposed between each of the pair of slits 102. The terminal opening 104 has a diameter greater then a diameter of each of the slits 102 so as to accommodate the pair of terminals 12 of the tuning fork 10. The terminal opening 104 is illustratively shown as being rectangular, but it should be appreciated that the shape of the terminal opening 104 is not limited to a rectangle, but may be circular, ovoid, or the like so long as the terminal opening 104 can accommodate the pair of terminals 12 of the tuning fork 10 and the second terminals 202 of an electronic component 200. The slits 102 have a width smaller than the thickness “T_{E}” of the support portions 16 of the tuning fork 10 so as to engage and retain the tuning fork 10 by an interference fit.

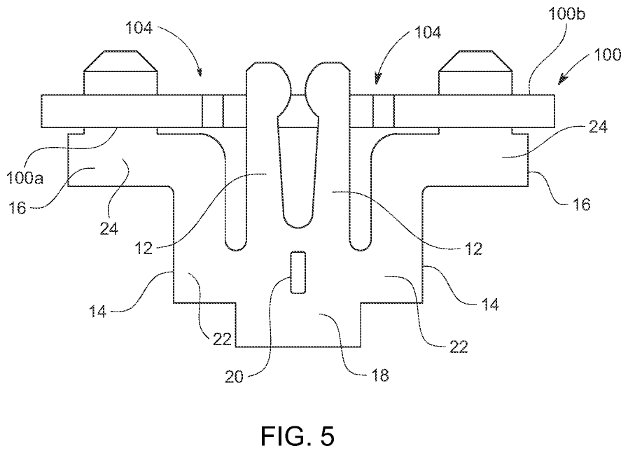

With reference now to FIG. 5, the tuning fork 10 is shown mounted to the bottom surface 100A of the circuit board 100. In particular, each support portion 16 is pressed into a corresponding slit 102 of the circuit board 100 wherein the pair of terminals 12 of the tuning fork extend through the terminal opening 104 of the circuit board 100. When fully seated, e.g. pressed against the bottom surface 100a of the circuit board 100, the support portions 16 and the terminals 12 of the tuning fork 10 extend beyond the top surface 100b of the circuit board 100. FIG. 5 illustrates that the end portion 26 of the support portions 16 are raised above the end of the pair of terminals 12.

### The Circuit Board Assembly

With reference now to FIGS. 3A-5, a circuit board 100 assembly is also provided. In one aspect, the circuit board 100 assembly includes a pair of tuning forks 10 and a circuit board 100. Each of the tuning forks 10 are identical to each other. Accordingly, a discussion of one of the tuning forks 10 is applicable to the other. For illustrative purposes, the tuning fork 10 described above may be implemented for use herein. The circuit board 100 includes two pair of slits 102 extending through the circuit board 100 and a pair of terminal openings 104. The slits 102 and the terminal openings 104 have the dimension and configuration described above.

In operation, the circuit board 100 assembly is assembled by first mounting a pair of tuning forks 10 onto the bottom surface 100a of the circuit board 100, wherein the support portions 16 are pushed through a respective slit 102 and the pair of terminals 12 of each tuning fork 10 are pushed through a corresponding terminal opening 104. This may be done manually or by automatically by a tool (not shown). In the case of a tool, the tool is configured to grip the engagement feature and push the tuning forks 10 into the desired slits 102. The tool may hold the tuning fork 10 in place, wherein an electronic component 200 may be inserted onto space between the respective terminals 12. Once in place, the tool may be removed.

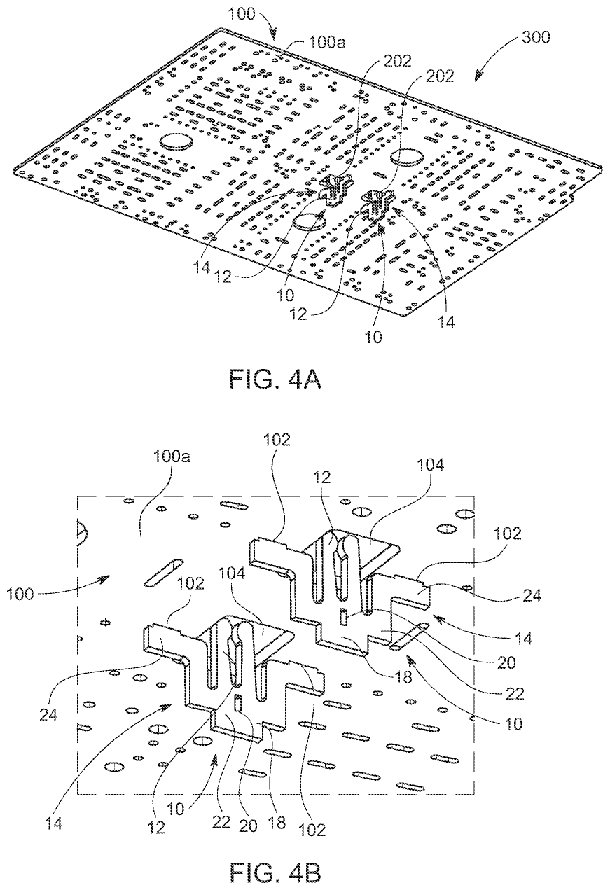

The electronic component 200 (shown in FIGS. 3A, 3B and 4A) includes a pair of second terminals 202 for completing an electric connection. The second terminals 202 are generally plate-shaped electrically conductive members. The pair of second terminals 202 are parallel to each and extend downwardly from a main body 204 of the electronic component 200. The electronic component 200 is illustratively shown as a fuse, but it should be appreciated that any other electronic component 200 may be adapted for use herein, illustratively including a relay, a capacitor or the like.

The electronic component 200 is mounted from the top surface 100b of the circuit board 100, wherein each of the second terminals 202 are seated within the gap between a corresponding pair of terminals 12 of the tuning forks 10. As shown in FIG. 4A, the second terminals 202 are pushed through the terminal openings 104 so as to extend beyond the bottom surface 100A of the circuit board 100. As such, the height “HE” of the electronic component 200 (shown in FIG. 3B) when mounted onto the circuit board 100 is less than conventional circuit board assemblies 500 as the second terminals 202 of the electronic component 200 would be seated above the circuit board 100 in conventional circuit board assemblies 500.

The operation is shown in a preferred aspect wherein two tuning forks 10 are used. However, it should be appreciated that a single tuning fork 10 may be used. Other aspects of the disclosure may deviate from what is shown in the drawings but still encompassed by the scope of the appended claims, to include the shape of the support portions 16, the orientation of the shoulders 14 with respect to the terminals 12, and the like.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A tuning fork for attachment to a circuit board, the tuning fork comprising:
a pair of terminals,
a pair of shoulders, each of the pair of shoulders extending orthogonal from a bottom of the pair of terminals so as to place the pair of terminals between each shoulder in the pair of shoulders; and
a pair of support portions extending upwardly from a corresponding one of the pair of shoulders, the pair of terminals disposed between the pair of support portions, the pair of support portions configured to engage the circuit board.

2. The tuning fork as set forth in claim 1, further including a base portion, the pair of terminals extending from the base portion.

3. The tuning fork as set forth in claim 2, wherein each of the pair of terminals, the pair of shoulders, the pair of support portions and the base portion is a plate-shaped member.

4. The tuning fork as set forth in claim 2, wherein the pair of terminals, the pair of shoulders, the pair of support portions and the base portion are coplanar.

5. The tuning fork as set forth in claim 2, wherein the each of the pair of shoulders includes an upright member and a transverse member, the transverse member orthogonal to the upright member.

6. The tuning fork as set forth in claim 5, wherein each upright member is spaced apart from a corresponding one of the pair of terminals.

7. The tuning fork as set forth in claim 2, wherein each of the pair of support portions includes an end portion, the end portion being tapered along at least one of a width, a height or a thickness of the corresponding one of the pair of support portions.

8. The tuning fork as set forth in claim 2, wherein the base portion includes a tool engagement feature.

9. The tuning fork as set forth in claim 2, wherein each of the pair of terminals includes a bulbous member disposed on an inner surface of each of the pair of terminals so as to oppose each other.

10. A circuit board assembly comprising:
a circuit board having a pair of slots spaced apart from each other and a terminal opening disposed between the pair of slots; and
a tuning fork, the tuning fork including:
a pair of terminals, each of the pair of terminals including a pair of shoulders, each of the pair of shoulders extending orthogonal from a bottom of a corresponding one the pair of terminals; and
a pair of support portions extending upwardly from a corresponding one of the pair of shoulders, the pair of terminals disposed between the pair of support portions, the pair of support portions configured to engage a corresponding one of the pair of slots so as to place the pair of terminals within the terminal opening of the circuit board.

11. The circuit board assembly as set forth in claim 10, wherein the circuit board includes a top surface and a bottom surface opposite of the top surface.

12. The circuit board assembly as set forth in claim 11, further including an electronic component, wherein the pair of terminals are mounted to the bottom surface of the circuit board and the electronic component is mounted to the top surface of the circuit board so as to be disposed in the terminal opening and the pair of terminals are secured to the electronic component through the terminal opening.

13. The circuit board assembly as set forth in claim 12, wherein the electronic component includes a pair of second terminals, each of the pair of terminals of the tuning fork configured to engage a corresponding second terminal in the pair of second terminals in a pinch-fit manner.

14. The circuit board assembly as set forth in claim 10, wherein the tuning fork further includes a base portion, the pair of terminals extending from the base portion.

15. The circuit board assembly as set forth in claim 14, wherein each of the pair of terminals, the pair of shoulders, the pair of support portions and the base portion is a plate-shaped member.

16. The circuit board assembly as set forth in claim 14, wherein the pair of terminals, the pair of shoulders, the pair of support portions and the base portion are coplanar.

17. The circuit board assembly as set forth in claim 10, wherein the each of the pair of shoulders includes an upright member and a transverse member, the transverse member orthogonal to the upright member.

18. The circuit board assembly as set forth in claim 17, wherein each upright member is spaced apart from a corresponding one of the pair of terminals.

19. The circuit board assembly as set forth in claim 10, wherein each of the pair of support portions includes an end portion, the end portion being tapered along at least one of a width, a height or a thickness of the corresponding one of the pair of support portions.

20. The circuit board assembly as set forth in claim 14, wherein the base portion includes a slot extending though the base portion and, wherein each of the pair of terminals includes a bulbous member disposed on an inner surface of each of the pair of terminals so as to oppose each other.
